(19) United States
(12) Patent Application Publication
(10) Pub. No.: US 2009/0024890 A1
(43) Pub. Date: Jan. 22, 2009

(54) CIRCUIT ARRANGEMENT, DATA PROCESSING DEVICE COMPRISING SUCH CIRCUIT ARRANGEMENT AS WELL AS METHOD FOR IDENTIFYING AN ATTACK ON SUCH CIRCUIT ARRANGEMENT

(75) Inventors: Giancarlo Cutrignelli, Graz (AT); Ralf Malzahn, Seevetal (DE)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/162,832

(22) PCT Filed: Feb. 5, 2007
(86) PCT No.: PCT/IB2007/050382

§ 371 Date: Jul. 31, 2008

(30) Foreign Application Priority Data
Feb. 9, 2006 (EP) 06101486.6
Feb. 5, 2007 (IB) PCT/IB2007/050382

(51) Int. Cl. G01R 31/3183; G06F 11/263

(52) U.S. Cl. 714/736; 714/E11.177

(57) ABSTRACT

In order to further develop a circuit arrangement (100), in particular an active shield, as well as a method for identifying at least one attack on the circuit arrangement (100), wherein test data are generated, the test data are transmitted via at least one group of data lines (50) being designed for carrying data signals in the form of regular data and/or in the form of the test data, the transmitted test data are received, the received test data are compared with expected test data, and any discrepancy between the received test data and the expected test data is ascertained or determined, in such way that less power is required for examining, in particular for identifying, if the circuit arrangement (100) has been attacked, it is proposed that part of the group of data lines (50) is selected to carry new or most recent test data having been generated.

The present invention relates to a circuit arrangement, in particular to an active shield, according to the preamble of claim 1.

The present invention further relates to a microcontroller, in particular to an embedded security controller, comprising such circuit arrangement.

The present invention further relates to a data processing device, in particular to an embedded system, for example to a chip card or a smart card, comprising such circuit arrangement.

The present invention further relates to a method for identifying at least one attack on at least one circuit arrangement, in particular on at least one active shield, according to the preamble of claim 7.

In integrated circuits the actual semiconductor components are arranged in a lower plane, the so-called active plane, whereas the wiring of the semiconductor components is implemented in planes lying further above, the so-called metal planes. Depending on the complexity of the circuit, a plurality of metal planes is required in order to carry out a complete wiring.

The individual metal planes are usually electrically isolated from one another by an insulation line. Since each additional metal plane leads to a considerable increase in costs in the production of the integrated circuit, in general, attempts are made to keep the number of metal planes as low as possible.

Further requirements are made of integrated circuits which comprise security-critical circuit components. These relate to the repulse of attacks to the integrated circuit, the aim of these attacks to covertly discover the internal processes in the security-critical components or the construction thereof and thus to obtain the opportunities for manipulation or for unauthorized operations. Such attacks are known as probing, forcing, F[ocused]I[on]B[eaming], etc.

In especially security-critical cases, the affected regions are covered with an active shield and, if appropriate, an additional metal plane is provided for this.

In the case of an active shield, regions of a circuit arrangement are covered with a multiplicity of additional lines for which voltage and/or current flow are monitored in order to be able to detect a physical attack. Thus, an active shield is a defensive system with built-in constraints to limit or prevent its offensive use. The general function of an active shield is for example described in prior art document U.S. Pat. No. 6,496,119 B1, in prior art document U.S. Pat. No. 6,798,234 B2, and in prior art document US 2005/0092848 A1.

In prior art document US 2005/0092848 A1 an integrated circuit as described in the technical field is disclosed. This conventional integrated circuit is designed for ensuring the security of an active shield without requiring an additional metal plane for this. To achieve this, data lines present anyway in the integrated circuit are used to construct an active shield. In particular, a group of data lines carrying regular data can be switched to carry test data and vice versa.

However, the simultaneous switching of all shield lines is rather power intensive and can affect the correct functionality of some security-critical circuits, for example memories, protected by the active shield, because high current peaks due to shield line switch occur.

Beside this, prior art document US 2005/0092848 A1 proposes to use predetermined test data, which can optionally be encrypted. Said test data can be transmitted at irregular intervals, for example under the control of a random number generator. Thus, according to prior art document US 2005/0092848 A1 active shield lines are switched based on a deterministic pattern or pseudo-random pattern.

However, the possibility to reproduce off-line an observed pattern can let an attacker be able, for instance, to force the expected pattern at some point of the shield lines, close to the receiving circuit, while being free to perform manipulations before the breakpoint itself. In this case, the evaluation device would not be able to detect the attack.

Starting from the disadvantages and shortcomings as described above and taking the prior art as discussed above into account, an object of the present invention is to further develop a circuit arrangement of the kind as described in the technical field as well as a method of the kind as described in the technical field in such way that less power is required for examining, in particular for identifying, if the circuit arrangement has been attacked.

The object of the present invention is achieved by a circuit arrangement comprising the features of claim 1, by a microcontroller comprising the features of claim 5, by a data processing device comprising the features of claim 6 as well as by a method comprising the features of claim 7. Advantageous embodiments and expedient improvements of the present invention are disclosed in the respective dependent claims.

The present invention is principally based on the idea to provide a low-power protective circuit arrangement for an integrated circuit, in particular to provide an integrated circuit having a low-power active shield, more particularly to provide an integrated circuit having a low-power random active shield.

In a normal operating state of a conventional active shield the transmitting device applies to each of the data lines, in particular to each of the shield lines, new or most recent test data having been generated by the data signal generating device.

In contrast thereto, according to the present invention only part of the group of data lines, in particular at least one shield line of the group of shield lines, are selected for being applied with the new or most recent test data. For applying the selected part of data lines with the new or most recent test data, the circuit arrangement advantageously comprises at least one data line enabling device being designed for enabling and disabling the selected part of the group of data lines to carry the new or most recent test data.

Thus, according to a preferred embodiment of the present invention the data lines, in particular the shield lines, are selectively enabled and disabled which leads to the advantage that electrical influence on non security-critical cases is prevented while maintaining the overall security.

Moreover, the selective enabling and disabling of part of the group of data lines prevents that high current peaks due to enabling or disabling of the data lines occur and thus prevent that the correct functionality of at least one security-critical circuit, such as of memory being protected by the circuit arrangement can be effected by high current peaks.

Furthermore, the selective enabling and disabling of part of the group of data lines, in addition to the possibility to toggle only one shield line at a time, with no need for test data encryption or for checksum calculation, is less power intensive in comparison to conventional protective circuit arrangements, in particular to conventional active shield lines. Accordingly, the circuit arrangement proposed by the present invention as well as the method for identifying at least one attack on at least one circuit arrangement proposed by the present invention save power.

The data signal generating device preferably generates the test data dynamically and/or randomly, in particular by means of at least one pseudo or true random number generating device. If the test data are generated randomly, it is not possible for attackers to reproduce the test data. Thus, the present invention can preferably be embodied as a random circuit arrangement, in particular as a random active shield.

Independently thereof or in combination therewith, the random number generating device can be designed for generating at least one signal for the data line selection device, in particular the random number generating device can be designed as selection signal generator. Thus, the data line for carrying the new or most recent test data can be selected randomly in particular by means of the at least one random number generating device.

The data lines, in particular the shield lines, carry the test data being transmitted by the transmitting device, being received by the receiving device and being compared with expected test data by the evaluation device. In case of intact data lines said test data are received identically by the receiving device.

If the received test data do not correspond to the transmitted test data, then, according to a preferred embodiment of the present invention, the evaluation device causes the circuit arrangement or at least one integrated circuit being arranged at the circuit arrangement to effect a function change.

The latter may be for example erasing data held in at least one memory, performing a reset, or generating an alarm. This leads to the advantage that an undesired manipulation or observation of the circuit arrangement can be prevented.

According to an advantageous embodiment of the present invention the test data are randomly generated on-the-fly, in such a way that a reduced number of data lines, in particular one or two data lines, are switching.

In this context switching means that
upon enabling one or several data lines having been selected, said at least one enabled data line switches from carrying at least one first kind of the data signals, in particular the regular data or older test data, to carrying the new or most recent test data, and
upon disabling one or several data lines having been selected, said at least one disabled data line switches from carrying the new or most recent test data to carrying the first kind of the data signals, in particular the regular data.

In this context, the selected part of the group of data lines can switch preferably simultaneously. Moreover, according to a preferred embodiment of the present invention the receiving part of the circuit arrangement, in particular the receiving device, is not connected with a multiplexer. The consequence of this is that the data lines are all simultaneously checked when enabled.

According to a particularly inventive refinement of the present invention, for selecting part of the group of data lines two levels of selection are proposed, with the purpose of reducing power. The first level is advantageously controlled by at least one counting device or counter, and the second level is advantageously controlled by the random number generating device.

In a special embodiment, both levels can be controlled by the random number generating device. The consequence is that an average toggling frequency can be guaranteed.

Independently thereof or in combination therewith the group of data lines is advantageously
arranged in an upper plane of the circuit arrangement,
situated at least in part above at least one security-critical circuit component being arranged in a lower plane of the circuit arrangement, said security-critical circuit component in particular comprising the detector module, the random number generating device and the data signal generating device, and
connected with the security-critical circuit component.

In such embodiment of the circuit arrangement or shielding circuit, the aim is to avoid physical manipulations of the upper metal layer(s), in order to reach signals placed in lower metal layer(s) and carrying sensitive data. It is then more important to make it hard to the hacker to reproduce the data sequence over the circuit arrangement, than to make the circuit arrangement toggling fast or random in time.

Therefore, according to an advantageous embodiment of the present invention random values are generated to be applied to the circuit arrangement. This favorable proposal rules out any checksum or C[yclic]R[edundancy]C[heck] in the evaluation device.

Instead, the check is made by comparing the test data coming from the data lines and being received by the receiving device against the same test data or a copy of the test data sent directly from the data signal generator, in particular sent directly from at least one further data signal generator being connected with the evaluation device.

Advantageously, this copy of test data, in particular this second copy of test data, preferably being generated by the data signal generator is itself protected by the circuit arrangement, in particular by the active shield.

Another key feature of a preferred embodiment of the present invention is the property to hold the previous test data, in particular the at least one previous random value being generated by the random number generating device, for each data line being not selected by the data line selection device and in particular being not modified by the data line enabling device. The test data being generated previously by the data signal generating device can advantageously be hold in at least one memory device, for example in at least one preferably gated register.

According to an expedient easy and low-power implementation of the present invention the memory device is connected to the data signal generating device and/or to the transmitting device. Thus, previous test data can be hold in the data signal generating device and/or in the transmitting device.

Furthermore, a preferred embodiment of the present invention addresses an issue which has not yet been taken into account in the related art. This issue is the propagation delay or transmission delay associated with the selected part of the group of data lines because the transmission time of the expected test data and the received test data might vary.

The evaluation device is responsible for comparing the expected test data values against the actual test data values received through the data lines. However, according to a preferred embodiment of the present invention the part of the group of data lines being selected for carrying the new or most recent test data having been generated by the data signal generating device does not obligatorily need to have the same transmission time as the data lines being used for transmitting the expected test data.

The selected part of the group of data lines can optionally comprise shorter data lines or longer data lines than the data lines being used for transmitting the expected test data.

The expected test data can in particular be transmitted via at least one direct data line.

Thus, the expected test data can for example be sent from the transmitting device to the receiving device through shorter data lines or through shorter wires, the shorter data lines or shorter wires themselves being protected by the circuit arrangement, in particular by the shield or by the group of data lines.

In this case the expected test data reach the receiving device through the circuit arrangement, in particular through the shield or through the group of data lines, in a longer time than the new or most recent test data. It is even possible that the transmission time of the respective expected test data and/or of the respective received test data differs from each data line carrying these expected test data or these received test data.

The consequence of this optional embodiment is that the evaluation device cannot compare the expected test data and the received test data at an arbitrary time but only at instants when the expected test data and/or the received test data are supposed to be stable at the side of the receiving device.

An especially advantageous embodiment of the present invention proposes to disable the comparison of the received test data with expected test data for the selected part of the group of data lines, in particular for the toggling line, for an interval greater than the longest propagation time of the data lines carrying the expected test data, in particular greater than the longest propagation time of data lines being assigned to the group of data lines and being not selected by the selection device, for example greater than the longest propagation time of the shield.

In case the propagation time or transmission time of the test data, in particular of the newest or most recent test data, is longer than the transmission time of the expected test data, it is proposed according to a preferred embodiment of the present invention to disable the comparison of the received test data with the expected test data for the selected part of the group of data lines for an interval greater than the longest propagation time or transmission time of the selected part of the group of data lines.

According to a preferred embodiment of the present invention the propagation delay or transmission delay associated with the selected part of the group of data lines can be provided by at least one clock device, in particular by the usage of at least one clock reference, and/or by at least one delay-matched acknowledgement line.

A favorable effect of this preferred embodiment is that the circuit arrangement offers a certain protection against destructive attacks, such as on the basis of F[ocused]I[on]B[eam]s, which physically modify the electrical connections, and thus the capacitances as well as the resistances of the wires.

Another favorable side effect of this preferred embodiment is that the circuit arrangement offers a certain protection also against non-destructive attacks, such as probing, which modify the capacitive load of the group of data lines. A modification of the capacitive load would lead to a modification of the propagation delay, and so to a failing check, provided that minimum propagation delay(s) and/or maximum propagation delay(s) are checked.

The present invention can favorably be implemented as an integrated circuit with at least one circuit arrangement as described above, in particular with at least one active shield as described above, the circuit arrangement being optionally designed for protecting at least one security-critical circuit component such as at least one memory device being assigned to the circuit arrangement and/or to the integrated circuit.

An essential feature of a preferred embodiment of the present invention being designed for generating the test data in particular randomly and/or in particular on-the-fly, in such a way that a reduced number of data lines, for example one shield line or two shield lines, is selected to carry the new or most recent test data, is that this preferred embodiment is able to ensure that the selected reduced number of data lines is switching simultaneously.

Moreover, an essential feature of an advantageous embodiment of the present invention is the ability to generate a random pattern while ensuring an average data line enabling and disabling activity, in particular while ensuring an average shield line toggling activity.

Furthermore an essential feature of an expedient embodiment of the present invention is that one or more data lines are selectively enabled and disabled, for instance
to prevent the active shield from electrically influencing sensitive operations or circuit blocks in non security-critical cases, or
to save power.

Beside this, an essential feature of a preferred embodiment of the present invention is that it can be easily adjusted to accommodate long propagation delays and/or varying propagation delays.

The present invention leads to the advantages of being implemented easily and of spending less energy because a reduced number of data lines is selected for carrying the newest or most recent test data. In a preferred embodiment even only one data line changes its carrying state when enabled or when disabled. Independently thereof or in combination therewith, the selected part of the group of data lines can advantageously be selected randomly.

In an advantageous embodiment of the circuit arrangement, in particular of an integrated circuit comprising such circuit arrangement, the group of data lines can be spread over a large chip area, possibly over the whole area; in order to improve coverage, the group of data lines can be laid out in a so-called brownian-like style.

This leads in conventional protective circuits to the following problems:
long propagation delay and/or varying propagation delay;
high capacitance associated to the data line, in particular to the shield line; and
high current peaks due to data line enabling or due to data line disabling, in particular due to shield line switch.

These problems are overcome by the above-described preferred embodiments of the present invention.

In general, the present invention can be applied to all integrated circuits which need to protect security-critical components. The optional time reference, such as the clock, can be easily tuned to be adapted to specific propagation delays.

The advantageous possibility to dynamically enable and/or to dynamically disable the selected part of the group of data lines allows avoiding electrical interference between the advantageously high capacitive group of data lines and at least one element to be protected, in particular at least one protected circuit, thus making such preferred embodiment of the present invention particularly suitable for sensitive blocks, such as for analog front-ends and memories.

The present invention is particularly suited for any contactless device, such as for a contactless chip card, for a contactless smart card, for a contactless electronic label or for a contactless electronic tag, but can also be designed into any contact chip card or contact smart card as well as into other identification devices, such as U[niversal]S[erial]B[us] tokens.

The present invention is for example suited to any high performance application requiring large memory and high security. This covers third generation (3G) wireless communications, banking, m[obile]-commerce, e[lectronic]-business and secure network access.

The present invention is particularly suited for leading-edge U[niversal]I[ntegrated]C [ircuit]C[ard]s, which include U[niversal]S[ubscriber]I[dentity]M[odule] applications and R[emovable]U[ser]I[dentity]M[odule] applications.

The present invention finally relates to the use of at least one circuit arrangement, in particular of at least one active shield, as described above and/or of the method as described above for protecting at least one integrated circuit against at least one attack, wherein the integrated circuit can be arranged in at least one data processing device, in particular in at least one embedded system, for example in at least one chip card or smart card, as described above in the field of public key cryptography, such as banking, online shopping, PayT[ele]V[ision] (for example pay-per-view), security, etc.

As already discussed above, there are several options to embody as well as to improve the teaching of the present invention in an advantageous manner. To this aim, reference is made to the claims respectively dependent on claim 1 and on claim 7; further improvements, features and advantages of the present invention are explained below in more detail with reference to three preferred embodiments by way of example and to the accompanying drawings where

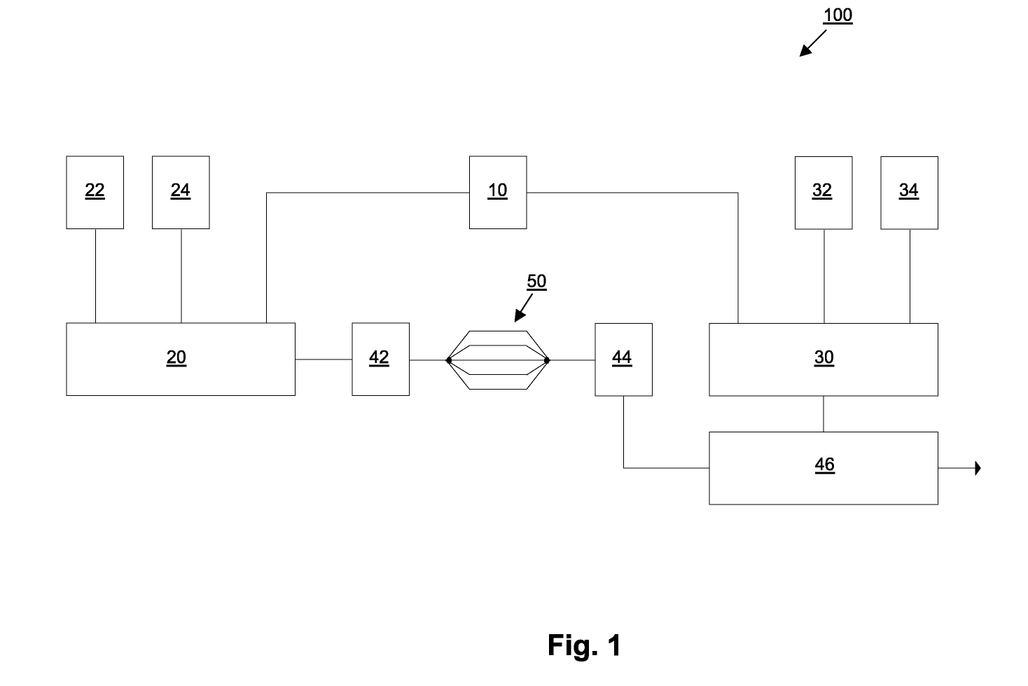

FIG. 1 schematically shows a first embodiment of the circuit arrangement of the present invention working according to the method of the present invention;

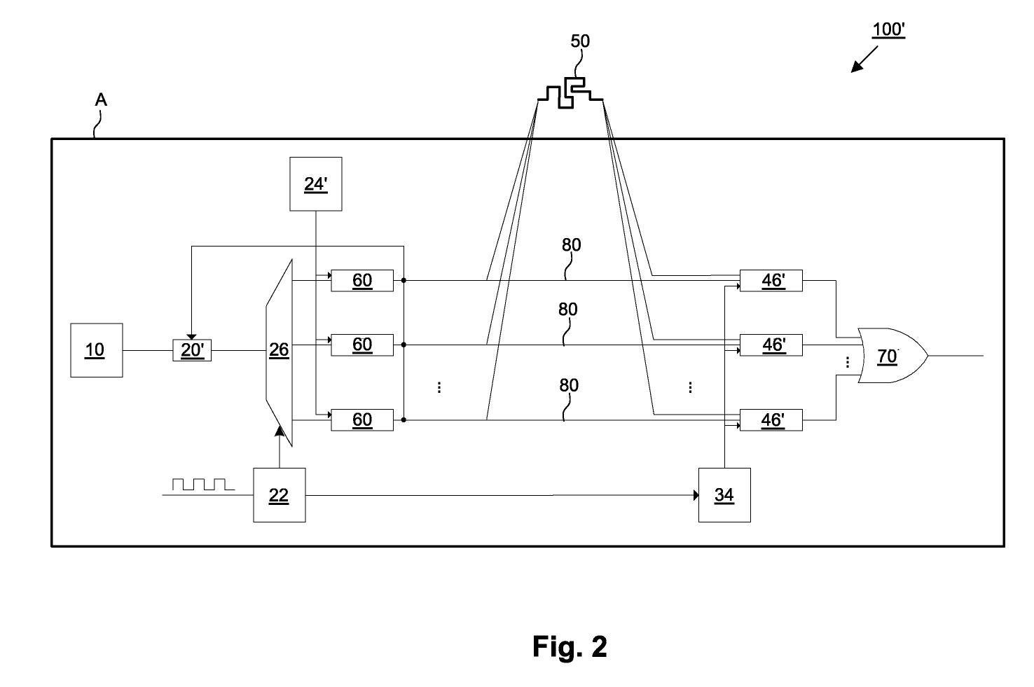

FIG. 2 schematically shows a second embodiment of the circuit arrangement of the present invention working according to the method of the present invention; and

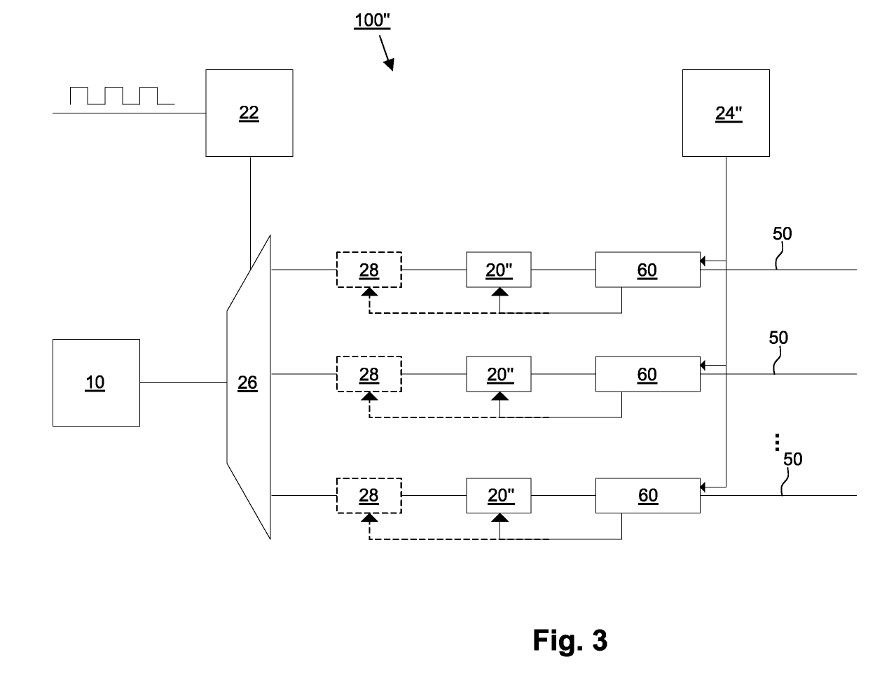

FIG. 3 schematically shows a third embodiment of the circuit arrangement of the present invention working according to the method of the present invention.

The same reference numerals are used for corresponding parts in FIG. 1 to FIG. 3.

In order to avoid unnecessary repetitions, the following description regarding the embodiments, characteristics and advantages of the present invention relates (unless stated otherwise)
to the first embodiment of the circuit arrangement 100 according to the present invention (cf. FIG. 1) as well as
to the second embodiment of the circuit arrangement 100′ according to the present invention (cf. FIG. 2) as well as
to the third embodiment of the circuit arrangement 100″ according to the present invention (cf. FIG. 3),
   all embodiments 100, 100′, 100″ being operated according to the method of the present invention.

FIG. 1 illustrates a first embodiment of a protective circuit 100, namely of an active shield, being assigned to an integrated circuit.

The integrated circuit has security-critical circuit components such as a detector circuit device being designed for identifying an attack on the integrated circuit, the detector circuit device comprising
a transmitting device 42 for transmitting test data,
a receiving device 44 for receiving the test data having been transmitted by the transmitting device 42 and
an evaluation device or evaluation circuit 46 for comparing the received test data with expected test data and for ascertaining any non-correspondence between the received test data and the expected test data.

The integrated circuit further comprises a group of data lines, namely a plurality of active shield lines 50
being designed for carrying data signals, in particular regular data and/or the test data,
being arranged in an upper plane (cf. FIG. 2),
being situated at least in part above the security-critical circuit components, in particular above the detector circuit, which security-critical circuit components are arranged in a lower plane A (cf. FIG. 2), and
being connected to at least part of the security-critical circuit components, in particular to the detector circuit.

The active shield 100 further comprises a random number generating device 10 being connected
with a first data signal generating device, namely with a first test data generator 20, and
with a second data signal generating device, namely with a second test data generator 30.

The first test data generator 20 is designed
for generating at least one first kind of data, in particular regular data, and/or for generating the expected test data and/or for generating the test data, and
for charging the group of data lines 50 with different signals, namely with the generated test data and with the first kind of data by means of the transmitting device 42.

The test data are carried in the plurality of active shield lines 50 from the transmitting device 42 to the receiving device 44; in addition to that, the test data are checked over the protective circuit 100 against the expected test data by means of the evaluation device 46 being connected with the receiving device 44.

The expected data can optionally be transmitted form the transmitting device 42 to the receiving device 44 via the group of active shield lines 50. However, expediently the expected test data are transmitted via one or more direct data lines 80 (cf. FIG. 2), wherein the direct data line(s) 80 itself (themselves) can be protected by the plurality of active shield lines 50.

Beneath to the random number generator 10 and to the transmitting device 42, the first test data generator 20 is connected
to a data line selection device, namely to a first shield line group selector 22 being designed for selecting part of the plurality of active shield lines 50 to carry new or most recent test data having been generated by the test data generator 20, and
to a data line enabling device, namely to a first shield line group enabler 24 being designed for enabling and disabling the selected part of the group of active shield lines 50 to carry the new or most recent test data.

The second test data generator 30 is connected
to the random number generator 10,
to a second shield line group selector 32,
to a second shield line group enabler 34, and
to the evaluation device 46.

The first test data generator 20 generates at defined or random time intervals new test data, i.e. a new pattern. This new pattern differs from the previous test data or previous pattern at most only by one bit.

Upon enabling one or several shield lines having been selected, said enabled shield line(s) switch(es) or toggle(s) from carrying the first kind of the data signals, in particular the regular data or older test data, to carrying the new or most recent test data.

The random number generator 10, the first shield line group selector 22 and the first shield line group enabler 24 control which line will toggle, when this line will toggle and if this line will toggle.

The second test data generator 30, the second shield line group selector 32 and the second shield line group enabler 34 implement the same algorithm at the receive side.

The first test data generator 20 and the second test data generator 30 can be instantiated or designed as a single device or block. Moreover, the first shield line group selector 22 and the second shield line group selector 32 can be designed as a single device or block, and the first shield line group enabler 24 and the second shield line group enabler 34 can be designed as a single device or block. The random number generator 10 advantageously is in any case the same block in either case.

The evaluation device 46 is responsible for the check of the received test data against the expected test data. Due to line propagation delay, advantageously the check is performed a certain time after the new test data or the new pattern is applied to the selected part of the group of shield lines 50. This selected shield line(s) can also be called test data line or toggling line.

On the other hand, it is not strictly required to switch or toggle the selected shield line(s) at regular intervals but the shield line(s) for carrying the new or most recent test data can be selected randomly and the switching or toggling itself can be performed randomly.

In other words, in the embodiment depicted in FIG. 1 the test data is randomly generated on-the-fly, in such a way that a reduced number of the group of active shield lines 50, possibly one active shield line, is switching or toggling between carrying the test data and carrying the first kind of data.

In case of two or more active shield lines of the plurality of active shield lines 50 being selected for switching or toggling, the selected active shield lines can switch or toggle simultaneously.

In FIG. 2, a second embodiment of a protective circuit, namely of an active shield 100′, is depicted.

In this embodiment a test data generator 20′ is connected to at least one multiplexing device or multiplexer 26. The multiplexer 26 is connected to at least one memory device or register 60, namely to at least one shield line group register, wherein each shield line group register 60 itself is connected
to at least one data line of the group of data lines 50 and
to a data line enabling device, in particular to a shield line group enabler 24′.

Optionally, a demultiplexer can be connected for example to the receiving device 44.

The multiplexer 26 is further connected to the test data generator 20′ and to the first shield line group selector 22. The test data generator 20′ can be provided with at least one output signal of the shield line group registers 60.

On the opposite side of the shield line group registers 60, each test data line of the group of data lines 50 is connected to an evaluation device, in particular to a respective comparator 46′.

Each comparator 46′ is connected to the second shield line enabler or line group check enabler 34 and to at least one alarm device or alarm generator 70 being designed for generating an alarm in case of non-correspondence between the received test data and the expected test data.

Beneath to the group of data lines 50, each comparator 46′ is further connected to the direct data line 80 being designed to carry the expected test data.

For example, the group of shield lines 50 can be divided into groups of n=4. However, it is to be noted that the total number of shield lines 50 is not obligatory a multiple of n wherein n is the number of shield lines collected into a group of shield lines 50.

In this exemplary case, the shield line group selector 22 can be implemented as a counter, which is selecting in turn a line group being assigned to a shield line group register 60.

The test data generator 20′, corresponding to the selected part of the group of shield lines 50 or to the targeted line group, receives a set of random bits from the random number generator 10, which amounts to log₂(n)+1=3 bits.

Of these log₂(n)+1 random bits, for example
two bits can then be used to select one shield line over four shield lines to be selected, in particular to be switched or toggled, and
one bit can be used to set the new test data or the next line value.

The test data generator 20′ is then able to create the new test data from the current test data which is fed back from the selected line group register 60.

In case a shield line group does not contain n=4 lines, and the selected line 52 is not existing, the new pattern can be neglected.

The new test data, having for example a maximum Hamming distance of one from the current test data, is then applied to the selected group of test data lines 50 and to the direct data lines 80.

With reference to the second embodiment of the circuit arrangement 100′ according to the present invention (cf. FIG. 2), it is distinguished between the active shield lines 50 and the direct data lines 80 because the latter (=the direct data lines 80) constitute an internal copy of the former (=the active shield lines 50), the direct data lines 80 being protected by the shield lines 50.

At the receive side, the comparators 46′ are checking the test data being carried by the active shield line(s) 50 against the expected test data being carried by the direct line(s) 80.

The line group check enabler 34 is responsible for suppressing the check between the “firing” time and the arrival time. It is to be noted that the active shield lines 50 and the direct lines 80 have a significantly different propagation time.

An easy implementation of the line group check enabler 34 can be realized by using the same time reference as of the line group selector 22, and by disabling the check of the evaluation device 46′ for a certain number of clock cycles after the firing edge, i.e. after the new or most recent test data have been transmitted. This action can be taken groupwise.

The bounding box with reference numeral A denotes the lower plane comprising security-critical circuit components, in particular comprising a circuit arrangement controlling device, namely comprising the whole active shield controller, which active shield controller itself is protected by the group of shield lines 50.

In the following, the toggling rate of the selected shield line(s) is exemplarily described:

In case the random bits comprise a uniform distribution, and the shield line group selector 22 is running at a rate fₛ, the average toggling frequency <f₁> or a single shield line having been selected is <f₁>=fₛ*1/n*1/2=fₛ/2n=fₛ/8 for n=4.

By construction, only a single shield line is selected in a group of shield lines 50, and only a group of shield lines 50 is selected at a time, therefore at most a single shield line having been selected is toggling at a time.

In addition, the shield line group enabler 24′ can selectively enable and/or disable single shield line groups 50. These can be easily implemented by using the gated shield line group registers 60.

It can be noticed then that the control granularity corresponds to the number n of shield lines collected into a group of shield lines 50.

According to a further improvement in FIG. 2, the configuration of the active shield line 100′ can be easily changed
to force the selected line to toggle, which means an average toggling frequency of fₛ/4, or
to select more groups of shield lines 50 at a time.

In FIG. 3, a further improvement of the embodiment of FIG. 2, namely an active shield 100″, is depicted.

In this further improvement, the multiplexer 26 is connected to at least one scrambling device 28, being designed for adding correlation between the new or most recent test data, in particular between the random data being generated by means of the random data generator 10, and the data being actually carried in the group of active shield lines 50, in particular the current test data and/or the first kind of data.

Each single data line or subgroup of data lines of the group of data lines 50 and optionally each single data line or subgroup of data lines of the direct data lines 80 (the latter being not depicted in FIG. 3 for reasons of clarity) is assigned
to a respective shield line group register 60,
to a respective data signal generating device, namely to a respective test data generator 20″, and
to a respective scrambling device or scrambler 28.

The scrambling device or scrambler 28 can be added before the respective test data generator 20″, so as to add correlation between the current line data values, in particular the test data and/or the first kind of data being currently carried in the shield line, and the next data values, in particular the new or most recent test data being carried in the selected shield line after the new or most recent test data has been generated.

Such improvement can involve
at least one XOR (=eXclusive OR) operation between the random bits and the current shield line data of each group of shield lines 50, in particular suitably reordered, and/or
at least one XOR (=eXclusive OR) operation between the random bits and the current shield line data of other groups of shield lines 50,
   such XOR (=eXclusive OR) operation being realizable by at least one XOR (=eXclusive OR) logical element, in particular by at least one XOR (=eXclusive OR) gate.

A further improvement of the present invention, in particular of the first embodiment of the active shield 100 and/or of the second embodiment of the active shield 100′ and/or of the third embodiment of the active shield 100″, derives from at least one self-timing property of the circuit arrangement, namely of the active shield 100, 100′, 100″.

The only timing constraint resides in that the check of the evaluation circuit or evaluation device 46 must not be performed during the interval

tₙₒ_{_{—}}ₐₗₐᵣₘ=[tₘᵢₙ_{_{—}}_{propag},tₘₐₓ_{_{—}}_{propag}].

In general, the capacitance of the group of shield lines 50 can be easily estimated from technology parameters, and from these technology parameters the propagation delays can be easily estimated.

The time tₙₒ_{_{—}}ₐₗₐᵣₘ is calculated starting from the “firing” time, such as the transmitting time of the test data.

It is then possible
to randomly generate firing times, with a minimum distance of tₘₐₓ_{_{—}}_{propag}, and
to calculate the time tₙₒ_{_{—}}ₐₗₐᵣₘ via at least one counter, reset at each firing time.

1. A circuit arrangement, in particular an active shield, comprising
at least one data signal generating device being designed for generating test data and expected test data,
at least one group of data lines being designed for carrying data signals, in particular regular data and/or the test data, and
at least one detector module being designed for identifying at least one attack on the circuit arrangement, the detector module comprising
at least one transmitting device for transmitting the test data,
at least one receiving device for receiving the test data having been transmitted from the transmitting device and
at least one evaluation device for comparing the received test data with the expected test data and for ascertaining or determining any discrepancy between the received test data and the expected test data,
characterized by
at least one data line selection device for selecting part of the group of data lines to carry new or most recent test data having been generated by the data signal generating device.

2. The circuit arrangement according to claim 1, characterized by at least one data line enabling device for enabling and disabling the selected part of the group of data lines to carry the new or most recent test data.

3. The circuit arrangement according claim 1, characterized in that the data signal generating device
generates the test data dynamically and/or randomly, in particular by means of at least one random number generating device, and
is connected
with the data line selection device, and/or
with the data line enabling device, and/or
with the transmitting device, and/or
with the evaluation device, and/or
with the random number generating device.

4. The circuit arrangement according to at least one of claims 1 to 3, characterized in that the group of data
is arranged in an upper plane of the circuit arrangement,
is situated at least in part above at least one security-critical circuit component being arranged in a lower plane of the circuit arrangement, said security-critical circuit component in particular comprising the detector module, the random number generating device, the data line selection device, the data line enabling device and the data signal generating device, and
is connected the security-critical circuit component.

5. A microcontroller, in particular an embedded security controller, comprising at least one circuit arrangement according to at least one of claims 1 to 4.

6. A data processing device, in particular an embedded system, for example a chip card or a smart card, comprising at least one circuit arrangement according to claim 1.

7. A method for identifying at least one attack on at least one circuit arrangement, in particular on at least one active shield, wherein
test data are generated,
the test data are transmitted via at least one group of data lines being designed for carrying data signals in the form of regular data and/or in the form of the test data,
the transmitted test data are received,
the received test data are compared with expected test data, and
any discrepancy between the received test data and the expected test data is ascertained or determined,
characterized in
that part of the group of data lines is selected to carry new or most recent test data having been generated.

8. The method according to claim 7, characterized in that the selected part of the group of data lines is enabled or disabled to carry the new or most recent test data wherein the data lines of the selected part of the group of data lines can be enabled preferably simultaneously and/or can be disabled preferably simultaneously.

9. The method according to claim 8, characterized in that
upon enabling one or several data lines having been selected, said at least one enabled data line switches from carrying at least one first kind of the data signals, in particular the regular data or older test data, to carrying the new or most recent test data, and
upon disabling one or several data lines having been selected, said at least one disabled data line switches from carrying the new or most recent test data to carrying the first kind of the data signals, in particular the regular data.

10. A computer program product directly loadable into the memory of at least one computer, comprising at least one software code portion for performing the method according to claim 7 when said computer program product is run on the computer, said computer program being in particular electronically distributable.

11. Use of at least one circuit arrangement, in particular of at least one active shield, according to at least one of claims 1 to 4 and/or of the method according to claim 7 for protecting at least one integrated circuit against at least one attack, wherein the integrated circuit can be arranged in at least one data processing device, in particular in at least one embedded system, for example in at least one chip card or smart card, according to claim 6 in the field of public key cryptography, such as banking, online shopping, PayT[ele]V[ision], security, etc.
